(19) United States
(12) Patent Application Publication
(10) Pub. No.: US 2026/0056230 A1
(43) Pub. Date: Feb. 26, 2026

(54) TEST PIN DEVICE

(71) Applicant: INGUN PRÜFMITTELBAU GMBH, Konstanz (DE)

(72) Inventor: David Stuhldreier-Kaufmann, Konstanz (DE)

(73) Assignee: INGUN PRÜFMITTELBAU GMBH, Konstanz (DE)

(21) Appl. No.: 19/102,656

(22) PCT Filed: Jun. 28, 2023
(86) PCT No.: PCT/EP2023/067738

§ 371 Date: Feb. 10, 2025

(30) Foreign Application Priority Data
Aug. 8, 2022 (DE) 10 2022 119 935.5

(51) Int. Cl. G01R 1/067; G01R 1/04

(52) U.S. Cl. CPC G01R 1/06722; G01R 1/04; G01R 1/06733

(57) ABSTRACT

The invention relates to a test pin (10) for electrically contacting a contact partner (20), in particular a planar surface (21) of a contact partner, comprising: a substantially sleeve-shaped main body (1); a contact head (3), which is disposed on a contact side (2a) of the main body (1), said contact side being proximate to the contact partner (20), and which has at least two partial segments (5a, 5b, 5c, 5d) extending axially from a base (4) of the contact head (3) ; wherein the partial segments (5a, 5b, 5c, 5d) each have at least one preferably rigid cutting element (6a, 6b, 6c, 6d) for cutting into and/or scratching open a surface of the contact partner (21), the cutting element extending from an end face of the partial segment in question, and the contact head (3) is designed for radial spreading or coming together of the cutting elements (6a, 6b, 6c, 6d) when a force (F) acting on the test pin (10) in the axial direction, in particular a compressive force, is applied.

### BACKGROUND OF THE INVENTION

The present invention relates to a test pin for reversibly contacting a contact partner, in particular for surface-contouring an energy storage.

Test pins or test pin devices with a contact head are generally known from the prior art and are used in test fields or other test contexts to check a test partner, such as an electronic assembly having a suitable socket section, for functionality. To do so, the test pin device is placed on the contact partner to be tested as a plug or contacts it. Subsequently, test signals are applied to the contact partner through suitable contacting. A plurality of test pins of this kind for being brought together with corresponding contact partners of a test object can also be provided in a common fastening device.

For example, generic WO 2012/136562 discloses a test pin comprising a sleeve-shaped housing, a sleeve-shaped contact element movably guided therein, and a pin-shaped element that interacts with the same, the latter and the contact element being axially preloaded in a first, uncompressed, non-contact position by means of separate elastic elements in the housing. When the contact element is inserted into a socket section to be contacted or tested, an axial force acts on the test pin through a stop that surrounds the contact element in the form of a collar, causing the contact element to be transferred to a second, cocked contact position, the pin-shaped element being pressed against an inner contact surface of the contact element, causing a radial widening of the contact head for the purpose of making contact with, i.e., contacting, the socket section by means of a circumferential surface of the test pin.

Test devices designed to contact an energy storage, in particular a battery, are known as well. In particular, contact can be made with a plane surface of the energy storage, in particular at a terminal. For example, DE 20 2018 104 812 U1 discloses a contact module for making electrical touch contact with a component, the contact module comprising a support having a contact side that can be assigned to the component and a connecting side facing away from the contact side, with at least two electrically conductive contact elements disposed therein, in particular in the form of a spring contact pin having a cockable contact head. A second contact pin can be disposed at an angle relative to a contacting direction, meaning the contact head in question is laterally displaced along the contact point of the component in question, causing the surface of the contact point to be scratched and a secure electrical contact to be established as a result. However, this can lead to an unwanted introduction of lateral force or lateral displacement of the entire test module, causing unwanted lateral forces to act on the device suspension or fastening.

### SUMMARY OF THE INVENTION

Based on the known state of the art, the object of the present invention is to provide an improved test pin for contacting an energy storage which enables high-quality contact during the test process while allowing for simple constructive realization and ease of maintenance.

This object is attained by a device and a test pin as disclosed herein. The dependent claims and disclosure describe advantageous embodiments of the present invention. All combinations of at least two of the features disclosed in the claims, the description and/or the figures fall within the scope of the invention.

The invention relates to a test pin for making electrical touch contact with a contact partner, in particular a plane surface of a contact partner, the test pin comprising an essentially sleeve-shaped body, a contact head disposed on a contact side of the body facing the contact partner, the contact head having at least two segments extending axially from a base of the contact head, wherein the segments each have at least one preferably rigid cutting element extending from a front end thereof for cutting into and/or scratching a surface of the contact partner, and that the contact head is configured in such a manner that the cutting elements radially widen and/or narrow when a force, in particular a compression force, acting on the test pin in an axial direction is applied.

The present invention enables the simple contacting of a surface, in particular at the terminal of an energy storage device for charging and/or testing purposes. The cutting elements provided at the front can be used to cut the passive surface of the contact partner, for example an oxide surface of aluminum. This results in a very low contact resistance, which minimizes the heating temperature, in particular when high currents are transmitted. The cutting elements provided preferably rigidly on the segments enable a very precise introduction of force For cutting the surface. The radial widening and/or narrowing of at least two cutting elements on the contact partner provides a radial spreading and/or radial contraction of the individual cutting elements, which enables stable and easy contacting. In particular, this also enables a reduction in axial contact force of the contact element in question and thus a reduction in mechanical stress on the energy storage.

Application of a force, in particular a compression force, acting on the test pin in the axial direction takes place in particular when the test pin and the contact partner to be contacted are moved relatively toward each other, for example by a test device disposed on the rear side of the test pin to hold the pin. When the test pin or the contact head comes into contact with the contact partner, an axial or compression force acts on the test pin and in particular also on the contact head. Contacting can be effected, for example, by axially moving the test pin onto the contact partner, which is held in place or in an immovable manner, or vice versa, i.e., by axially moving the contact partner onto the contact pin, which is held in a place.

In a preferred embodiment, the axially extending segments of the contact head and/or the cutting elements disposed thereon are circumferentially distributed, preferably evenly, about a center axis of the contact head. This allows the applied axial force to be distributed particularly evenly across the segments, in particular minimizing an unwanted introduction of lateral force to the test pin when the cutting elements widen and/or narrow.

Further preferably, the axially extending segments of the contact head and/or the cutting elements disposed thereon are disposed at a radially outward offset relative to a center axis of the contact head, preferably by the same radial distance from the center axis.

The segments are further preferably formed by at least one or more preferably slot-like recess on a side of the contact head facing the contact partner, the recesses each running parallel to a center axis of the contact head. The recesses extend from the side of the contact head facing the contact partner, preferably with the same length, to the base of the contact head. Preferably, at least one, in particular slot-like, recess is provided, meaning the contact head comprises at least two segments that extend axially and preferably parallel to each other. In another preferred embodiment, the contact head comprises two recesses which are disposed perpendicular to each other and which intersect in the center axis of the contact head. As a result, the contact head has four segments, which are preferably parallel to each other.

Further preferably, the contact head has a central hole which is coaxially with a center axis of the test pin or the contact head. The central hole can be designed for the feed-through and/or mounting of a sensor element, such as a temperature sensor. The sensor element or a sensor head of the sensor element can preferably extend almost as far as the cutting elements or be set back from the latter within the contact head. Alternatively or additionally, the hole can be designed for the feed-through of an inner conductor for additional or extended contacting of the contact partner. Alternatively or additionally, the hole can also be designed as a cooling channel for transporting cooling fluid, in particular cooled air, onto the contact partner or a contacting point of the contact head and the contact partner.

In another preferred embodiment, the contact head is mounted in such a manner that it can at least partially move axially within the sleeve-shaped body and is preloaded by an elastic element. The body preferably has a central, preferably essentially hollow cylindrical guiding portion in which the elastic element is disposed and at least part of the contact head, in particular a proximal base of the contact head, is mounted in an axially movable manner.

The contact head is preferably disposed to axially move in the body in such a manner that it is preloaded against a stop element by the elastic element, in particular an annular shoulder, when in a first extended non-contact position and at least partially cocked or cockable inside the body against the preload force of the elastic element when in a second contact position. The first non-contact position corresponds to the default state of the test pin, in which there is no contact with a contact partner.

In a preferred embodiment, the test pin comprises a pin element that is mounted in the body in a preferably immovable manner, the pin element being configured to interact with the contact head as a function of position in such a manner that when the contact head is cocked in the contact position of the test pin, the pin element engages a central opening portion and radially widens the segments of the contact head and the cutting elements disposed thereon in a preferably uniform manner in the process. The pin element and the opening portion interacting with it are preferably concentric with the center axis of the test pin and of the contact head. The opening portion is disposed on a side of the base of the contact head facing the contact partner or in a portion of the contact head associated with the segments. The opening portion can be a tapering opening or through hole which a distal portion of the pin element engages and radially widens the segments of the contact head in the process. The pin element preferably comprises a shaft with a constant external diameter and an at least partially tapering distal portion.

The pin element is preferably immovably disposed in a central guiding portion of the sleeve-like body. The elastic element preferably surrounds the pin element. The elastic element can be disposed or preloaded between a first circumferential shoulder of a proximal portion of the pin element and a shoulder disposed at the end of the base of the contact head.

In a preferred embodiment, the test pin comprises only one elastic element, which is further preferably disposed in a guiding portion of the sleeve-like body.

In another preferred embodiment, the pin element comprises a contoured portion on its outer circumferential surface and downward of a distal portion in the axial direction of movement, the contoured portion preferably having a reduced outer diameter. The contoured portion is configured to interact with the contact head as a function of position in such a manner that as the contact head is cocked further, the contoured portion engages the central opening portion after the distal portion and, in doing so, radially narrows the segments of the contact head in a preferably uniform manner and in the direction of their default position in the non-contact position of the contact head.

The opening portion of the contact head comprises a tapered portion and, preferably on both sides in the direction of movement, radially widened portions associated with it. The contact head is configured to sequentially interact with the pin element in such a manner that when a contact partner is contacted and the contact head is cocked as a result, the segments or the cutting elements disposed on them first undergo a preferably uniform radial widening and then, with further cocking, a preferably uniform radial narrowing. The sequential radial widening and subsequent radial narrowing of the segments or the cutting elements disposed on them allow for a particularly effective contact with the contact partner.

In a preferred alternative embodiment, the contact head is configured to interact with a distal opening and/or with an inner circumferential surface of a preferably hollow cylindrical guiding element disposed on the body as a function of position in such a manner that, when the contact head is cocked in a contact position of the test pin, the opening and/or the inner circumferential surface radially narrows the segments of the contact head or the cutting elements disposed thereon in a preferably uniform manner. The preferably hollow cylindrical guiding element can be mounted on the body and/or on the contact head in an axially movable manner by means of a second elastic element, which is preferably an exponential spring. The second elastic element can be preloaded between a rear annular shoulder of the body and a proximal end face of the guiding element. In addition, in the non-contact position, the guiding element can be preloaded against an annular shoulder provided on the body.

If the second elastic element is an exponential spring or a spring having an exponential spring force when compressed, a contact force applied to the contact partner can first be increased so that the cutting elements can penetrate the surface to be contacted, preferably perpendicularly, before a radial force acts on the cutting elements, causing the surface to be cut and/or scratched by the cutting elements.

In another alternative embodiment, the contact head can be formed integrally on the contact side of the body. In this case, the segments and the associated cutting elements are disposed in such a manner that an axial contact force on the test pin leads to a preferably uniform widening or narrowing of the cutting elements. In this case, the cutting elements preferably have a cutting edge or edge shape that is angled in relation to the surface to be contacted. The cutting edge or the cutting edge shape is disposed radially in an axial top view, meaning an axial contact pressure of each cutting element leads to radial bending or widening of said cutting element relative to a center axis of the contact head.

The respective cutting elements of the contact head are configured to at least partially cut into and/or scratch a preferably plane and/or passive surface of the contact partner. In an axial top view, each cutting element comprises a cutting edge or a cutting edge shape that extends radially outward. Alternatively or additionally, the cutting elements can have other cutting edge shapes, in particular a circumferentially tangential cutting edge or cutting edge shape in an axial top view. This means that the cutting edge or the cutting edge shape is essentially linear and, in an axial top view of the contact head, tangential to a circle concentric with the center axis or perpendicular to a predefined radius. The individual cutting edges of the respective cutting elements of the contact head are preferably tangential to the same circle or disposed at the same radial distance from the center axis.

Each segment of the contact head can also have a plurality of cutting elements. These can have a similar design or different designs.

### BRIEF DESCRIPTION OF THE DRAWINGS

Specifications, advantageous effects and details of the present invention will be explained below with reference to the purely schematic, merely exemplary drawings.

FIG. 1a: is a side view of a first preferred embodiment of a test pin according to the invention;

FIGS. 1b-1d: are sectional views of the test pin of FIG. 1a in different positions;

FIG. 2a: is a sectional side view of a variation of the preceding embodiment of a test pin according to the invention;

FIG. 2b: shows the test pin of FIG. 2a in a contact position;

FIGS. 3a-3e: are sectional side views of a second preferred embodiment of the test pin;

FIGS. 4a, 4b: are different views of a variation of the preceding embodiment of a test pin according to the invention;

FIGS. 5a-5e: are different views of a third preferred embodiment of the test pin;

FIGS. 6a-6b: are different views of another preferred contact head configuration;

FIGS. 7a-7b: are different views of other preferred contact head configurations;

FIGS. 8a-8b: are different views of other preferred contact head configurations; and

FIGS. 9a-9b: show another preferred contact head configuration.

### DETAILED DESCRIPTION

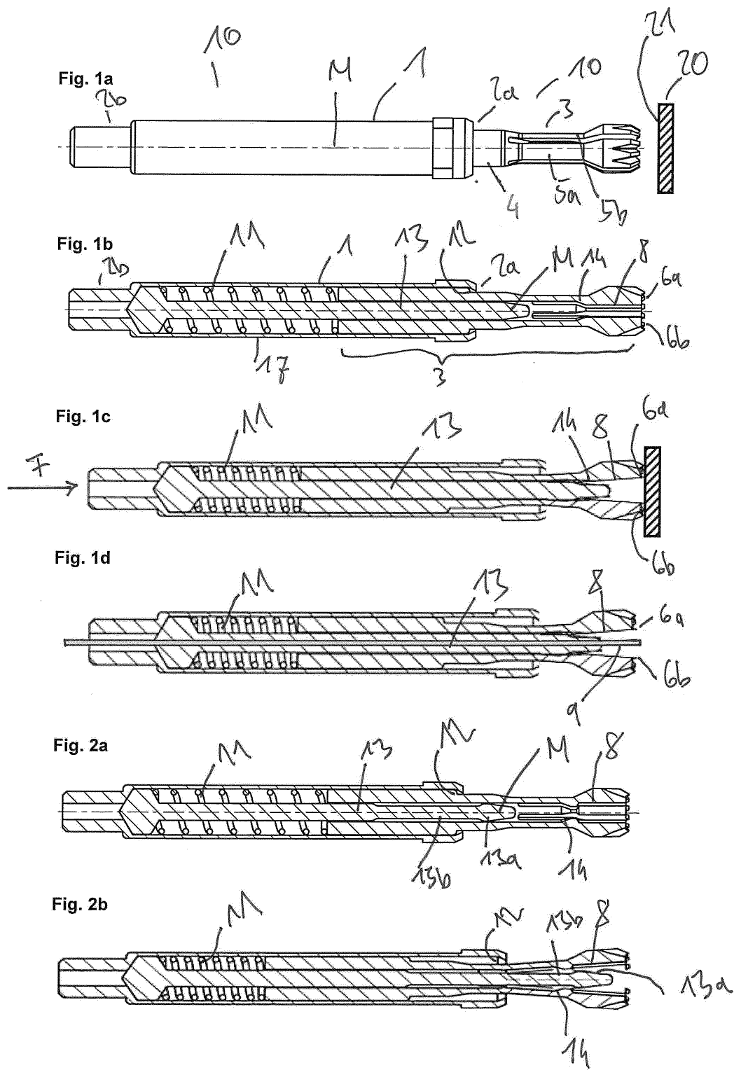

FIGS. 1a to 1d show a first preferred embodiment of a test pin 10 according to the invention for making electrical touch contact with, in particular, a plane surface 21 of a contact partner 20, such as a terminal of an energy storage.

The test pin has an essentially sleeve-shaped body 1 with a contact side 2a facing the contact partner 20 and an opposite connecting side 2b facing away from the contact partner. Furthermore, the test pin comprises a contact head 3 disposed on the contact side and having a base 4 on a rear side, i.e., a side facing away from the contact partner 20, and segments 5a, 5b extending from the base 4 toward the contact partner 20.

The contact head 3 is guided and mounted in a central guiding portion 17 of the test pin in an at least partially axially movable manner by means of the base 4. The guiding portion 17 has an elastic element 11 which preloads the contact head 3 into the non-contact position of the test pin 10 shown in FIGS. 1a and 1b. The elastic element 11 can be the only elastic element of the test pin 10 and is disposed between a rear stop in the guiding portion 17 and an opposing end face of the contact head 3 facing away from the contact partner 20. The elastic element 11 presses the base 4 of the contact head 3 against a stop 12 provided on the contact side 2a.

The contact head 3 comprises at least two segments 5a, 5b, which extend axially from the base 4 of the contact head and each have a cutting element 6a, 6b which extends from one end thereof and is preferably rigid, i.e., immovable in relation to the segments 5a, 5b. The cutting element 6a, 6b is preferably formed integrally, i.e., in one piece, with the associated segment 5a, 5b in each case. The cutting elements 6a, 6b are configured to cut into and/or scratch a surface 21 of the contact partner 20, in particular what is referred to as a passive surface, which is produced by oxidation.

The contact head is configured in such a manner that the cutting elements radially widen and/or narrow when a force F acting on the test pin 10 in an axial direction is applied. The at least two segments 5a, 5b and the cutting elements 6a, 6b disposed thereon are widened, i.e., spread, radially outward or narrowed radially inward in an axial top view of the test pin. In this context, “radially” means that, in an axial top view, the widening or narrowing of the individual elements occurs in the radial direction from a center axis of the contact head. The radial widening or narrowing of the cutting elements allows them to move, starting from an initial contact position on the contact partner, along the surface of the contact partner or essentially parallel to said surface and to cut into and scratch said surface in the process.

FIG. 1b shows a sectional view in the first extended non-contact position. The test pin has a central axial hole 8 disposed in the contact head 3 and extending through the entire contact head 3. In the non-contact position, a pin element 13, which is preferably mounted immovably in the body 1, engages said hole 8 at least partially. The pin element 3 is preferably made of solid material. Alternatively, the pin element 3 itself can also have a through hole in which sensors or other components such as an inner conductor 9 (see FIG. 1d) can be disposed or routed. Furthermore, a through hole of this kind can also provide a cooling channel for transporting cooling fluid, in particular cool air.

The pin element 13 is configured to interact with the contact head 3 as a function of position. In particular, during cocking of the contact head 3 in the body 1, a distal portion 13a of the pin element 13 engages a central opening portion 14 of the hole 8. The distal portion 13a can in particular be a tapering of the hole 8, preferably a continuous tapering in the direction of movement of the pin element 13 during cocking. When the pin element 13 engages the opening portion 14, the segments 5a, 5b of the contact head 3 are thus spread apart, as illustrated in FIG. 1c.

When the test pin 10 makes contact with a contact partner 20, the segments 5a, 5b are initially placed on the contact partner 20 with the cutting elements 6a, 6b disposed at the end before a simultaneous transverse or radial movement of the individual cutting elements 6a, 6b occurs parallel to the surface 21 on contact partner 20 with increasing contact force F through the interaction between the pin element 13 and opening portion 14 under continuous axial contact pressure (see FIG. 1c). When the contact pressure is released, i.e., when the test pin 10 is moved in the opposite direction to the pressure, the spring force of the elastic element 11 returns it to the non-contact position shown in FIGS. 1a, 1b.

FIGS. 2a, 2b show the test pin described above with a modified configuration of the pin element 13 and the opening portion 14. They are now designed in such a manner that when the test pin 10 is transferred from a non-contact position to a contact position, the segments 5a, 5b sequentially spread and narrow on the surface 21 of the contact partner 20. In this case, the pin element 13 is contoured and, in particular, has a contoured portion 13b with a reduced outer diameter, which is located downward of the distal portion 13a in the axial direction of movement. When the contact head 3 is being cocked, the distal portion 13 is first introduced into the opening portion 14 with a reduced diameter of the through hole 8, causing the widening of the segment described above. During further cocking, the contoured portion 13b interacts with the opening portion 14, the reduced external diameter causing the segments 5a, 5b to close or narrow again.

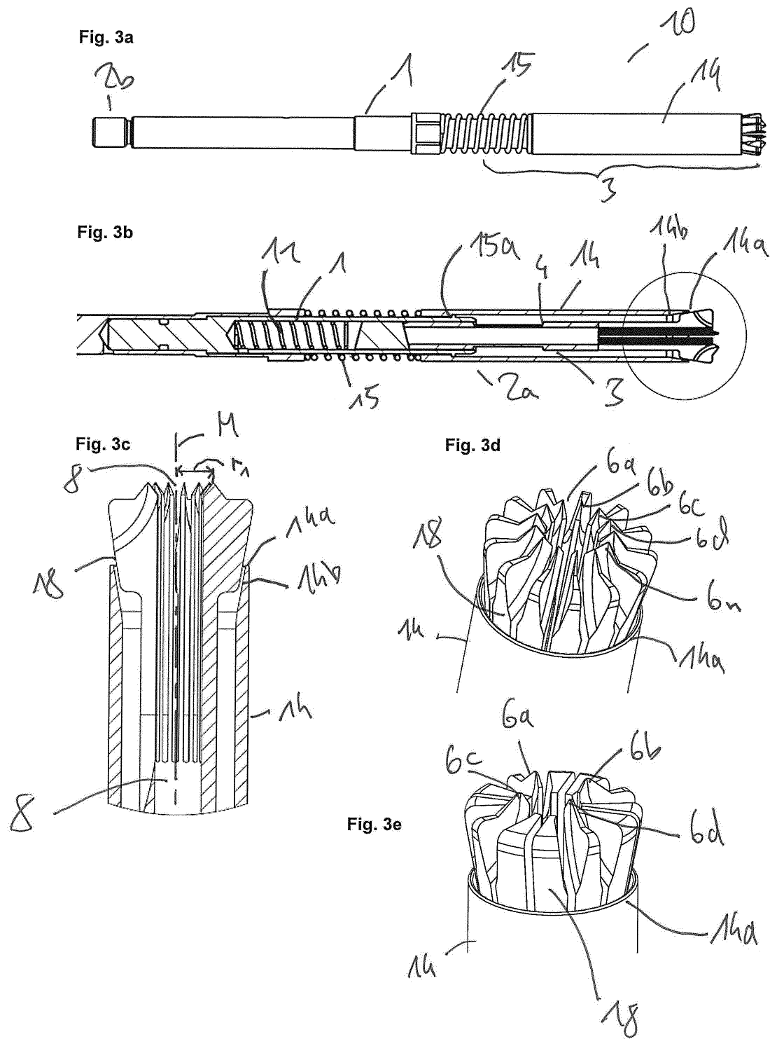

FIGS. 3a to 3e show another preferred embodiment of the test pin 10, which, instead of the pin element 13, has a hollow cylindrical guiding element 14 mounted on the body 1 and/or on the contact head 3 in an axially movable manner. The example shown has a plurality of segments 5a, . . , 5n, which each have a cutting element 6a, . . . , 6n. At the circumference, the segments 5a, . . . , 5n are enclosed or held by the guiding element 14. The guiding element 14 is preloaded in the direction of the non-contact position from the body by a second elastic element 1, the guiding element 14 being pushed against a stop 15a provided on the body 1. Analogously to the previous embodiment, the individual segments 5a, . . . , 5n are axially extending elements which extend from a common base 4 of the contact head 3.

The contact head 3 is designed to interact with a distal opening 14a and/or with an inner circumferential surface 14b of the hollow cylindrical guiding element 14 as a function of position in such a manner that when the contact head is cocked, the opening 14a and/or the inner circumferential surface 14b of the segments 5a,. . . , 5n of the contact head 3 radially narrow in a preferably uniform manner. The individual segments 5a, . . . , 5n can each have an outer or circumferential surface 18 which widens toward the contact partner and which is mounted in a corresponding inner circumferential surface 14b, which preferably widens conically outward at least in part.

FIGS. 3d and 3e show two slightly modified embodiments for a possible contact head 3, which differ in the number of segments 5a, . . . , 5n with cutting elements 6a, . . . , 6n. In particular, the embodiment according to FIG. 3e has two segments without cutting elements between the respective segments with cutting elements.

The axially extending segments 5a, . . . , 5n of the contact head 3 and/or the cutting elements 6a, . . . , 6n disposed thereon are disposed at a radially outward offset relative to a center axis M of the contact head 3, preferably by the same radial distance r₁ from the center axis M (see also FIG. 3c).

The segments 5a, . . . , 5n are evenly distributed circumferentially. The cutting elements 6a, . . . , 6n associated with the respective segments are preferably also evenly distributed circumferentially. The respective cutting elements 6a, . . . , 6n form a preferably essentially annular contact surface of the respective cutting elements on the surface 21 to be contacted. The annular contact surface is continuously reduced in diameter by the radial narrowing of the cutting elements 6a, . . . , 6n according to the invention.

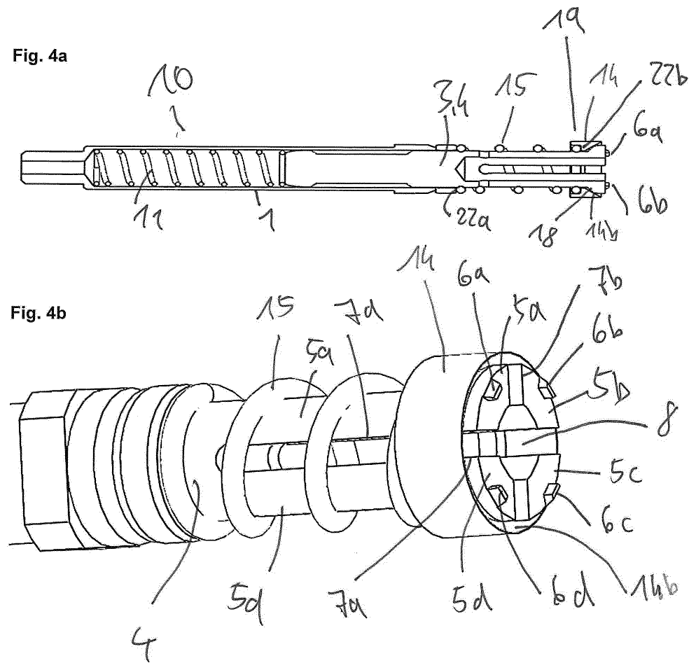

FIGS. 4a, 4b show a modified test pin according to the preceding embodiment, in which the hollow cylindrical guiding element 14 has a smaller longitudinal extension and, in particular, surrounds only a distal end portion 19 of the contact head 3. Analogously to the previously described embodiment, the segments 5a, 5b, 5c, 5d guided therein also have an outer or circumferential surface 18 which widens toward the contact partner and which is mounted in a corresponding inner circumferential surface 14b, which preferably widens conically outward at least in part.

The segments 5a, 5b, 5c, 5d are formed by two slot-like recesses 7a, 7b on a side of the contact head 3 facing the contact partner 20, the recesses 7a, 7b each being disposed parallel to a center axis M of the contact head 3 and intersecting perpendicularly therein. The segments 5a, 5b, 5c, 5d each have the shape of a sector of a circle with a central hole 8 when viewed from above.

The second elastic element 15 is preferably an exponential spring which is mounted on the body 1 and/or on the contact head 3 in a axially movable manner. In particular, the elastic element is preloaded between a rear annular shoulder 22a of the body and a proximal annular shoulder 22b of the guiding element 14. If the second elastic element is an exponential spring, a contact force applied to the contact partner when contacting the contact partner can first be increased so that the cutting elements can penetrate the surface to be contacted before a radial force acts on the cutting elements, causing the surface to be cut and/or scratched by the cutting elements.

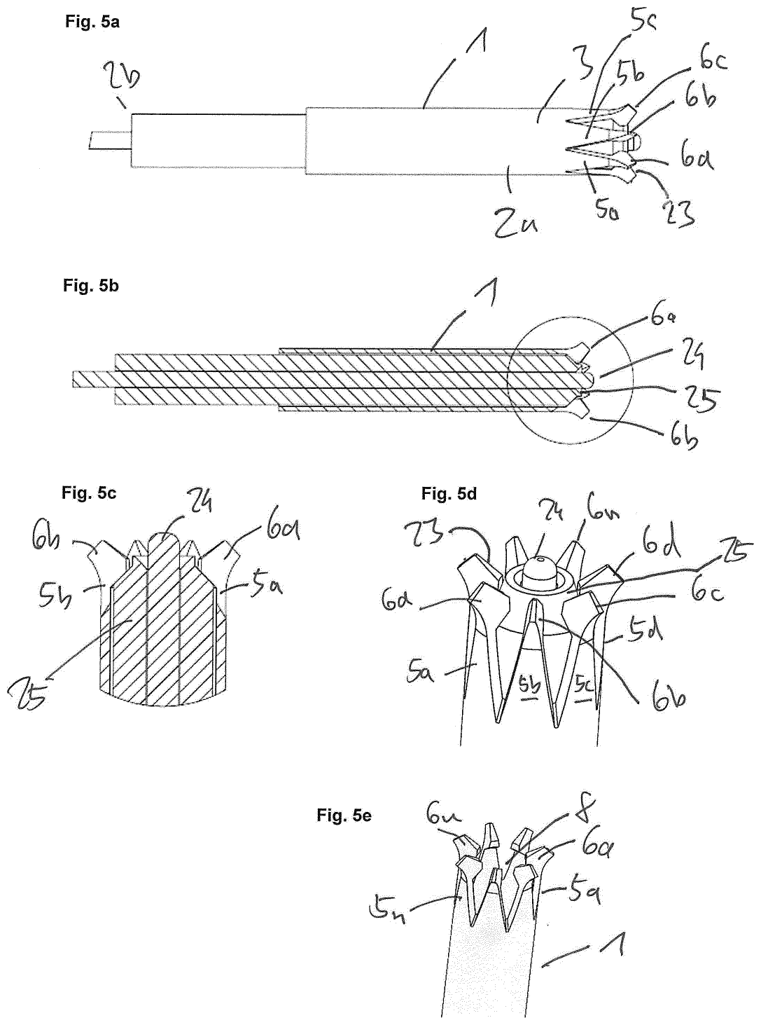

FIGS. 5a to 5e show another preferred embodiment, in which the contact head 3 is formed integrally on the contact side 2a of the body 1 or is rigidly, i.e. immovably, connected thereto. The segments 5a, . . . , 5n and the associated cutting elements 6a, . . . , 6b are disposed in such a manner that an axial contact force on the test pin 10 leads to a preferably uniform widening of the cutting elements. The segments are formed by preferably essentially triangular recesses in a sleeve-shaped circumferential surface of the contact head 3.

The cutting elements each preferably have a cutting edge 23 that is angled in relation to the surface to be contacted. The cutting edge shape 23 is preferably disposed essentially radially in an axial top view so that an axial contact pressure of each cutting element leads to a radial bending or widening of each cutting element relative to a center axis M of the contact head 3.

A temperature sensor 24, which can be disposed in a stop sleeve 25 surrounding it, can be provided in a central hole 8 of the body 1. FIG. 5e shows an embodiment without the temperature sensor 24 disposed therein. Alternatively or additionally, an inner conductor for voltage measurement, for example, can be accommodated in the hole 8 as a sensor element. The inner conductor can, for example, be a known spring-loaded contact pin. In addition or alternatively, the hole 8 can provide a cooling channel by means of which cooled air, in particular, can be transported as a cooling fluid to a contact point of the contact head and the contact partner.

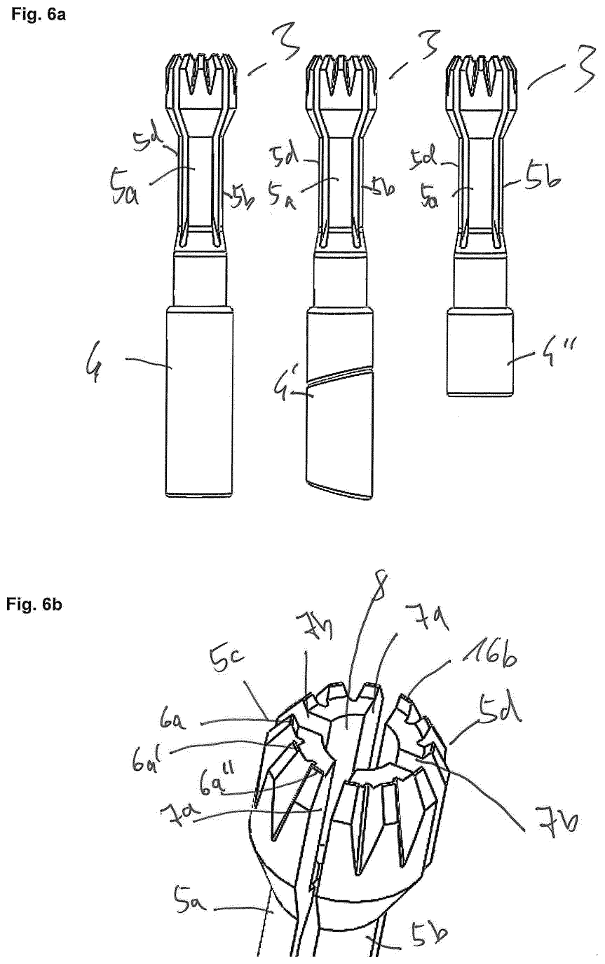

FIG. 6a shows various configurations of a contact head 3 having four circle-segment-like segments 5a, 5b, 5c, 5d extending axially from a base 4; the respective bases 4, 4′, 4″ in the figure shown can be designed differently in length and/or configuration. A greater axial length of the base 4 can lead to improved signal or current transmission.

As shown in FIG. 6b, the segments 5a, 5b, 5c, 5d may each have two or more cutting elements 6a, 6a′, 6a″, which are circumferentially tangential to a ring-shaped contact surface of the cutting elements on a surface of the contact partner 20, for example. The cutting elements disposed in such a manner lead to a scratching or scraping of the surface to be contacted in the event of an annular spreading.

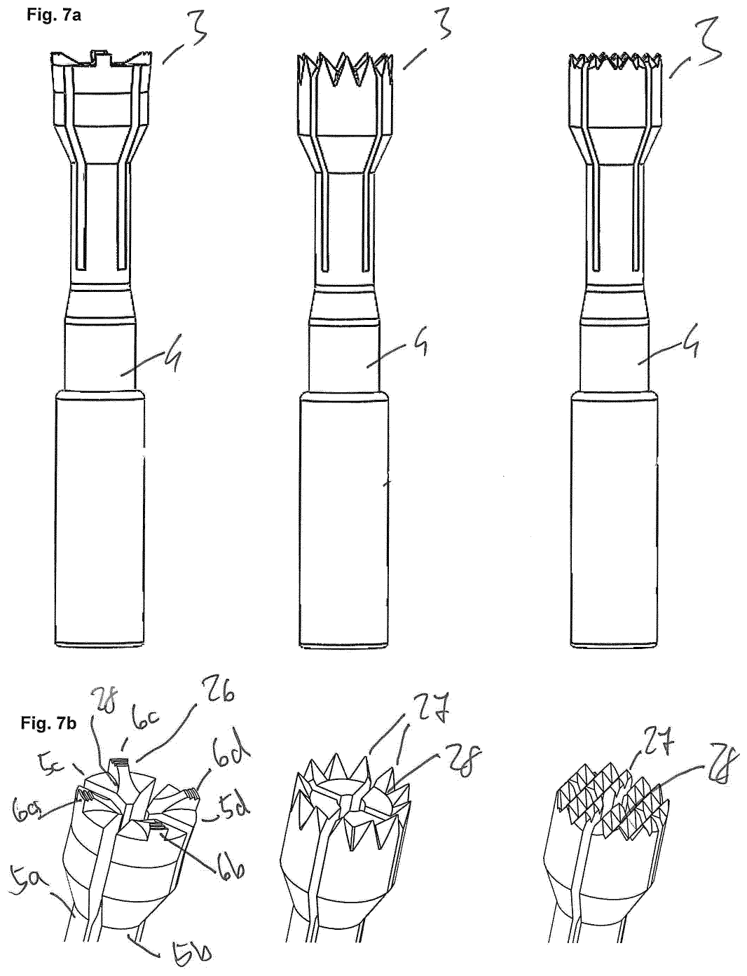

FIGS. 7a and 7b show further possible embodiments for the respective contact head 3 of the test pin. The respective cutting elements 6a, . . . , 6n can be groove-shaped elements 26, for example, as shown in FIG. 7b. Alternatively, the cutting elements 6a, . . . , 6n can also be point-shaped or pyramid-shaped, as shown in the two illustrations on the right in FIG. 7a and b. Pointed or pyramidal elements of this kind can only be disposed in a circumferential area of the end face 28 of the contact head 3 or can be distributed evenly across the entire end face.

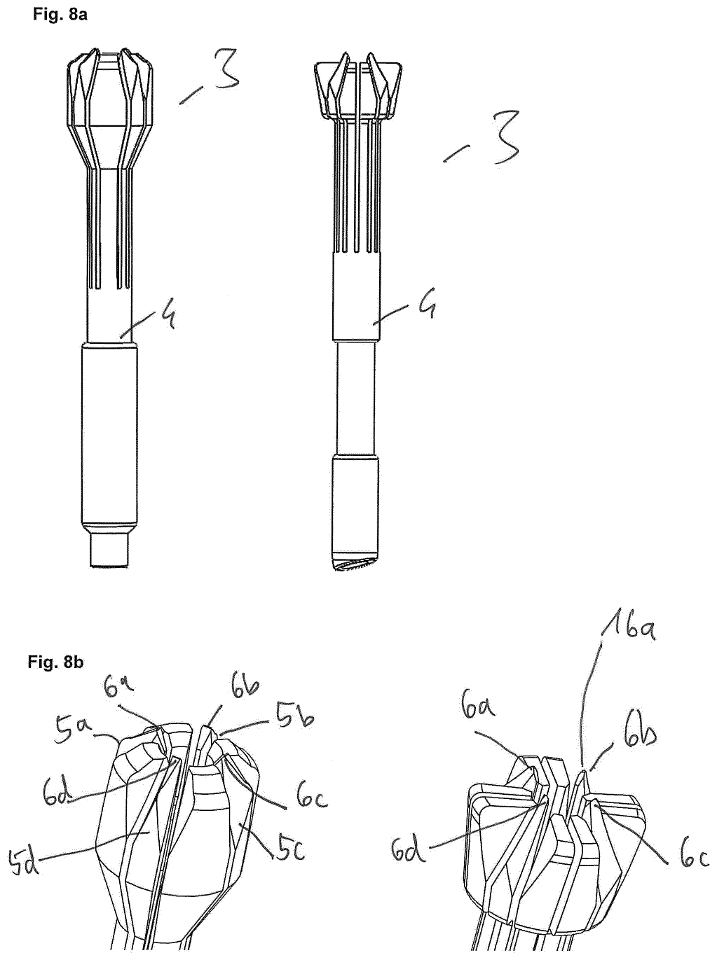

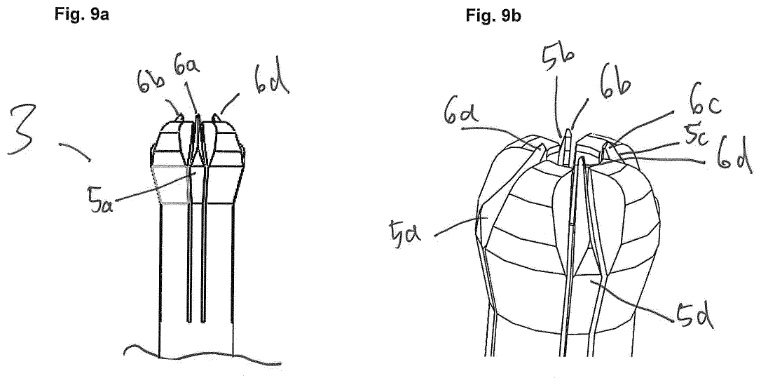

FIGS. 8a, 8b and 9a, 9b show further possible embodiments of the contact head 3 according to the invention, each having radial (FIG. 8b right; FIG. 9b) or tangential (FIG. 8b left) cutting edges 23 of the respective cutting elements 6a, 6b, 6c, 6d or cutting edges 23 perpendicular to the radial orientation.

### Reference Signs

1 body
2a contact side
2b connecting side
3 contact head
4 base of contact head
5a, . . . , 5n segments
6a, . . . , 6n cutting element
7a, 7b recess
8 central hole
9 sensor element/inner conductor
10 test pin
11 elastic element
12 stop element
13 pin element
13a distal portion
13b contoured portion
14 guiding element
14a distal opening
14b inner circumferential surface
15 second elastic element
15a stop of guiding element
16a, b radial tangential cutting edge
17 central guiding portion body
18 outer surface
19 end portion of contact head
20 contact partner
21 surface contact partner
22a annular shoulder body
22b annular shoulder guiding element
23 cutting edge
24 temperature sensor/inner conductor
25 stop sleeve
26 groove-shaped configuration
27 tip-shaped configuration
28 end face of contact head
M center axis
r1 radial distance
F axial force/compression force

1. A test pin (10) for making electrical touch contact with a contact partner (20), the test pin (10) comprising
an essentially sleeve-shaped body (1), a contact head (3) disposed on a contact side (2a) of the body (1) facing the contact partner (20), the contact head (3) having at least two segments (5a, 5b, 5c, 5d) extending axially from a base (4) of the contact head (3),
wherein the segments (5a, 5b, 5c, 5d) each have at least one preferably rigid cutting element (6a, 6b, 6c, 6d) extending from a front end thereof for cutting into and/or scratching a surface (21) of the contact partner (20), and wherein the contact head (3) is configured in such a manner that the cutting elements (6a, 6b, 6c, 6d) radially widen and/or narrow when a force (F) acting on the test pin (10) in an axial direction is applied.

2. The test pin according to claim 1, wherein the axially extending segments (5a, 5b, 5c, 5d) of the contact head and/or the cutting elements (6a, 6b, 6c, 6d) disposed thereon are circumferentially distributed, about a center axis (M) of the contact head (3).

3. The test pin according to claim 1, wherein the axially extending segments (5a, 5b, 5c, 5d) of the contact head (3) and/or the cutting elements (6a, 6b, 6c, 6d) disposed thereon are disposed at a radially outward offset relative to a center axis (M) of the contact head (3), by the same radial distance (r1) from the center axis (M).

4. The test pin according to claim 1, wherein the segments (5a, 5b, 5c, 5d) are formed by at least one or more slot-like recesses (7a, 7b) on a side of the contact head (3) facing the contact partner (20), the recesses (7a, 7b) each running parallel to a center axis (M) of the contact head (3).

5. The test pin according to claim 1, wherein the contact head (3) has a central hole (8) which is coaxial with a center axis (M) of the test pin (10) and in which a sensor element (9), or an inner conductor for contacting the contact partner (20) is accommodated and/or which provides a cooling channel for transporting a cooling fluid.

6. The test pin according to claim 1, wherein the contact head (3) is mounted in such a manner that it can at least partially move axially within the sleeve-shaped body (1) and is preloaded by an elastic element (11).

7. The test pin according to claim 1, wherein the contact head (3) is disposed to axially move in the body (1) in such a manner that it is preloaded against a stop element (12), by the elastic element (11) when in a first extended non-contact position and at least partially cocked inside the body (1) against the preload force of the elastic element (11) when in a second contact position.

8. The test pin according to claim 1, wherein the body (1) has a pin element (13) mounted therein in an immovable manner, the pin element (13) being configured to interact with the contact head (3) as a function of position in such a manner that when the contact head (3) is being cocked in a contact position of the test pin (10), the pin element (13) engages a central opening portion (14) and radially widens the segments (5a, 5b, 5c, 5d) of the contact head (3) in a uniform manner.

9. The test pin according to claim 8, wherein the pin element (13) has a contoured portion (13b) on its outer circumferential surface and downward of a distal portion (13a) in the axial direction of movement, the contoured portion (13b) having a reduced outer diameter and being configured to interact with the contact head (3) as a function of position in such a manner that as the contact head (3) is cocked further, the contoured portion (13b) engages the central opening portion (14) after the distal portion (13a) and radially narrows the segments (5a, 5b, 5c, 5d) of the contact head (3) in a uniform manner in the process.

10. The test pin according to claim 8, wherein the sleeve-like body (1) has a central guiding portion (17) in which the pin element (13) and, surrounding the latter, the elastic element (11) of the test pin (10) axially extend.

11. The test pin according to claim 1, wherein the contact head (3) is configured to interact with a distal opening (14a) and/or with an inner circumferential surface (14b) of a hollow cylindrical guiding element (14) disposed on the body (1) as a function of position in such a manner that when the contact head (3) is being cocked in a contact position of the test pin (10), the opening (14a) and/or the inner circumferential surface (14b) radially narrows the segments (5a, 5b, 5c, 5d) of the contact head (3) in a uniform manner.

12. The test pin according to claim 11, wherein the preferably hollow cylindrical guiding element (14) is mounted on the body (1) and/or on the contact head (3) in an axially movable manner by means of a second elastic element (15).

13. The test pin according to claim 1, wherein the contact head (3) is formed integrally on the contact side (2a) of the body (1).

14. The test pin according to claim 1, wherein the cutting elements (6a, 6b, 6c, 6d) of the contact head (3) are configured to at least partially cut into and/or scratch a plane and/or passive surface (21) of the contact partner (20).

15. The test pin according to claim 1, wherein the cutting elements (6a, 6b, 6c, 6d) each have a cutting edge (16a) extending radially outward in an axial top view and/or a cutting edge (16b) disposed tangentially at the circumference.

16. The test pin according to claim 1, wherein each segment (5a, 5b, 5c, 5d) of the contact head (3) has a plurality of cutting elements.

17. The test pin according to claim 1, wherein the test pin is for making electrical touch contact with a plane surface (21) of a contact partner.

18. The test pin according to claim 7, wherein the stop element (12) is an annular shoulder.

19. The test pin according to claim 12, wherein the second elastic element (15) is an exponential spring.
